(19) United States
(12) Patent Application Publication
(10) Pub. No.: US 2011/0237052 A1
(43) Pub. Date: Sep. 29, 2011

(54) METHOD FOR MANUFACTURING SEMICONDUCTOR DEVICE

(76) Inventors: Ichiro MIZUSHIMA, Yokohama-Shi (JP); Shinji Mori, Yokohama-Shi (JP)

(21) Appl. No.: 13/047,136

(22) Filed: Mar. 14, 2011

(30) Foreign Application Priority Data
Mar. 24, 2010 (JP) 2010-67774

(51) Int. Cl. H01L 21/20

(52) U.S. Cl. 438/478; 257/E21.09

(57) ABSTRACT

According to an embodiment of the present invention, a method for manufacturing a semiconductor device includes: forming an epitaxial crystal from a seed crystal exposed between first and second structures; heating the epitaxial crystal at a temperature equal to or less than a melting point of the epitaxial crystal to migrate the epitaxial crystal; and migrating the epitaxial crystal to form plural aggregates between the first and second structures.

### CROSS-REFERENCE TO RELATED APPLICATION

This application is based upon and claims the benefit of priority from prior Japanese Patent Application No. 2010-67774, filed on Mar. 24, 2010, the entire contents of which are incorporated herein by reference.

### FIELD

Embodiments of the present invention relate to a method for manufacturing a semiconductor device.

### BACKGROUND

Conventionally there is well known a method for manufacturing a semiconductor device. For example, in the method for manufacturing a semiconductor device, a functional layer is formed on a substrate on which projections and recesses are formed, and the functional layer is subjected to an annealing process to produce a device.

The functional layer has a structure in which a first functional material and a second functional material whose surface energy is larger than that of the first functional material are mixed or the first functional material and the second functional material are stacked. In the method for manufacturing a semiconductor device, the functional layer is irradiated with a laser beam to melt the functional layer, and the first and second functional materials are moved while separated into the recess and projection due to the difference in surface energy, thereby forming a pit pattern or a line pattern on the substrate.

However, in the conventional method for manufacturing a semiconductor device with state-of-the-art fine patterns, it is necessary to previously form the pattern on the substrate by a method for directly drawing the pattern on the substrate with the laser beam or an electron beam, a photolithographic method, or the like. The small-size pattern is hardly formed on the substrate due to a resolution limit of each method.

### BRIEF DESCRIPTION OF THE DRAWINGS

FIG. 1A to FIG. 1F are main-part sectional views illustrating processes of a method for manufacturing a semiconductor device according to a first embodiment of the invention;

FIG. 2A to FIG. 2F are main-part sectional views illustrating processes of a method for manufacturing a semiconductor device according to a second embodiment of the invention;

FIG. 3A to FIG. 3H are main-part sectional views illustrating processes of a method for manufacturing a semiconductor device according to a third embodiment of the invention;

FIG. 4A to FIG. 4E are main-part sectional views illustrating processes of a method for manufacturing a semiconductor device according to a fourth embodiment of the invention;

FIG. 5 is a plan view illustrating a semiconductor substrate after the annealing process in a method for manufacturing a semiconductor device of the fifth embodiment; and

FIG. 6 (a) is a plan view illustrating a semiconductor substrate before the annealing process in a method for manufacturing a semiconductor device according to a sixth embodiment of the invention, and FIG. 6 (b) is a plan view illustrating the semiconductor substrate after the annealing process.

### DETAILED DESCRIPTION

According to an aspect of an embodiment of the present invention, there is provided a method for manufacturing a semiconductor device comprising: forming an epitaxial crystal from a seed crystal exposed between first and second structures; heating the epitaxial crystal at a temperature equal to or less than a melting point of the epitaxial crystal to migrate the epitaxial crystal; and migrating the epitaxial crystal to form a plurality of aggregates between the first and second structures.

According to another aspect of an embodiment of the present invention, there is provided a method for manufacturing a semiconductor device comprising: forming an epitaxial crystal on a structure from a seed crystal exposed below the structure; heating the epitaxial crystal at a temperature equal to or less than a melting point of the epitaxial crystal to migrate the epitaxial crystal; and migrating the epitaxial crystal to form plural aggregates on the structure.

### First Embodiment

### Method for Manufacturing Semiconductor Device

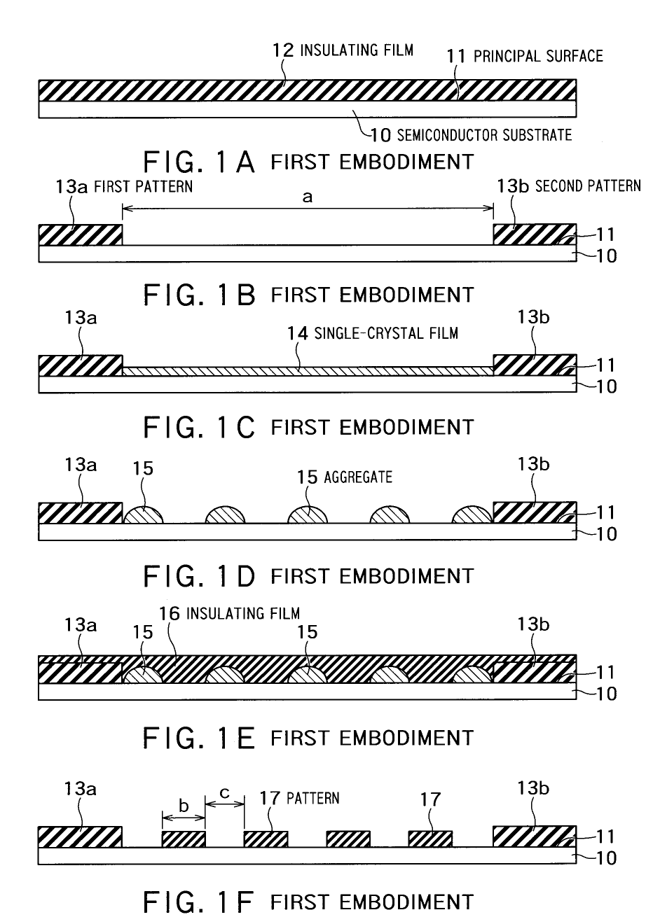

FIG. 1A to FIG. 1F are main-part sectional views illustrating processes of a method for manufacturing a semiconductor device according to a first embodiment of the invention. The method for manufacturing a semiconductor device of the first embodiment will be described below.

As illustrated in FIG. 1A, an insulating film 12 is formed on a principal surface 11 of a semiconductor substrate 10 by a CVD (Chemical Vapor Deposition) method, a thermal oxidation method, or the like.

For example, the semiconductor substrate 10 is made of a material having a lattice constant, which is close to that of the single-crystal film 14 to a degree that the single-crystal film 14 can epitaxially be grown, and a melting point higher than that of the single-crystal film 14.

For example, the semiconductor substrate 10 of the first embodiment is a silicon substrate containing mainly silicon.

For example, the insulating film 12 is made of a material having a melting point higher than that of the single-crystal film 14. In the first embodiment, for example, the insulating film 12 is a silicon oxide film.

As illustrated in FIG. 1B, the insulating film 12 is patterned by a photolithographic method, an RIE (Reactive Ion Etching) method, or the like to form a first pattern 13a that is of the first structure and a second pattern 13b that is of the second structure.

For example, an interval a between the first and second patterns 13a and 13b is 90 nm. A width of each of the first and second patterns 13a and 13b is equal to the interval a. FIG. 1B to FIG. 1F partially illustrate the first and second patterns 13a and 13b.

For example, the first and second patterns 13a and 13b forms a line and space pattern having the interval a and the width a. For example, the first and second patterns 13a and 13b may be a pattern having a size of a resolution limit of the photolithographic method or a pattern having a size larger than the resolution limit. The first and second structures are not limited to the insulating film, but the first and second structures may be made of a material that is migrated at a temperature higher than the melting point of the single-crystal film 14.

As illustrated in FIG. 1C, a single-crystal thin film is epitaxially grown from the principal surface 11 of the semiconductor substrate 10 exposed between the first and second patterns 13a and 13b, thereby forming the single-crystal film 14.

For example, the single-crystal film 14 that is of the epitaxial crystal is made of a material having a lattice constant, which is close to that of the semiconductor substrate 10 to a degree that the single-crystal film 14 can epitaxially be grown with the exposed semiconductor substrate 10 as a seed crystal. At this point, the single-crystal film 14 is made of a material that is migrated at a temperature lower than the melting points of the semiconductor substrate 10 and the insulating film 12. The single-crystal film 14 is made of a material, such as a tin-doped silicon film and a germanium-doped silicon film, which is migrated at a temperature lower than the melting points of the semiconductor substrate 10 and the insulating film 12. In the first embodiment, for example, the single-crystal film 14 is a germanium film having a thickness of 5 nm.

For example, the single-crystal film 14 can be formed so as to contain at least 20% germanium. For example, the annealing temperature, at which the single-crystal film 14 can migrate, decreases. The temperature at which the migration of the single-crystal film 14 is started is about 900° C. for the germanium concentration of 20%, about 850° C. for the germanium concentration of 30%, and about 800° C. for the germanium concentration of 40%. The silicon-germanium has the melting point of about 1300° C. for the germanium concentration of 20%, and the silicon-germanium has the melting point of about 938.25° C. for the germanium concentration of 100%. Therefore, the annealing process is performed at a temperature equal to or less than the melting point of the epitaxial crystal formed on the semiconductor substrate 10.

Then the single-crystal film 14 is subjected to the annealing process in a deoxidizing ambient such as hydrogen. For example, the annealing process is performed at 600° C. for minutes (for example, for 2 to 3 minutes). The single-crystal film 14 migrated by the annealing process becomes plural aggregates 15 when the temperature is lowered to room temperature. For example, as illustrated in FIG. 1D, the aggregates 15 are migrated at equal intervals based on the aggregates 15 migrated on side-face sides of the first and second patterns 13a and 13b. The aggregates 15 are linearly formed along the directions of the first and second patterns 13a and 13b.

Preferably the annealing temperature ranges from 400 to 700° C., more preferably from 500 to 600° C. However, a time for the annealing process is lengthened with decreasing annealing temperature.

For example, the aggregate 15 has the maximum thickness of about 10 nm. For example, a width of the aggregate 15 depends on the thickness of the epitaxially-grown single-crystal film 14. For example, the annealing process is performed by a method for irradiating the single-crystal film 14 with an energy ray or a method for heating the single-crystal film 14 with a heater.

As illustrated in FIG. 1E, an insulating film 16 is formed on the semiconductor substrate 10 by the CVD method or the like. For example, the insulating film 16 can be made of the material identical to that of the insulating film 12.

As illustrated in FIG. 1F, the aggregates 15 are selectively removed using a solution containing hydrogen peroxide water or a mixed solution of HF/HNO₃/H₂O, thereby obtaining plural patterns 17 of the insulating films 16. The plural patterns 17 become a line and space pattern in which the patterns 17 having widths b are arrayed with intervals c between the first and second patterns 13a and 13b. For example, the width b and the interval c of the pattern 17 are equal to each other. For example, the width b and the interval c are 10 nm. Then the semiconductor substrate 10 is processed with the plural patterns 17 as a mask, and the desired semiconductor device is obtained through well-known processes.

### Effect of First Embodiment

According to the method for manufacturing a semiconductor device of the first embodiment, the regularly-arrayed plural aggregates 15 are formed by the self-organization obtained by the annealing process of the single-crystal film 14, so that the line and space pattern having the size smaller than the resolution limit of the photolithographic method or the like can be formed.

According to the method for manufacturing a semiconductor device of the first embodiment, the plural aggregates 15 are regularly arrayed by the self-organization obtained by the annealing of the single-crystal film 14. Therefore, when compared with the case in which the similar structure is formed by the photolithographic method or the like, the number of processes can be decreased to shorten a time necessary to produce the semiconductor device. Additionally, according to the method for manufacturing a semiconductor device of the first embodiment, a manufacturing cost of the semiconductor device can be reduced.

### Second Embodiment

A second embodiment of the invention differs from the first embodiment in that the thickness of the single-crystal film 14 is larger than that of the first embodiment.

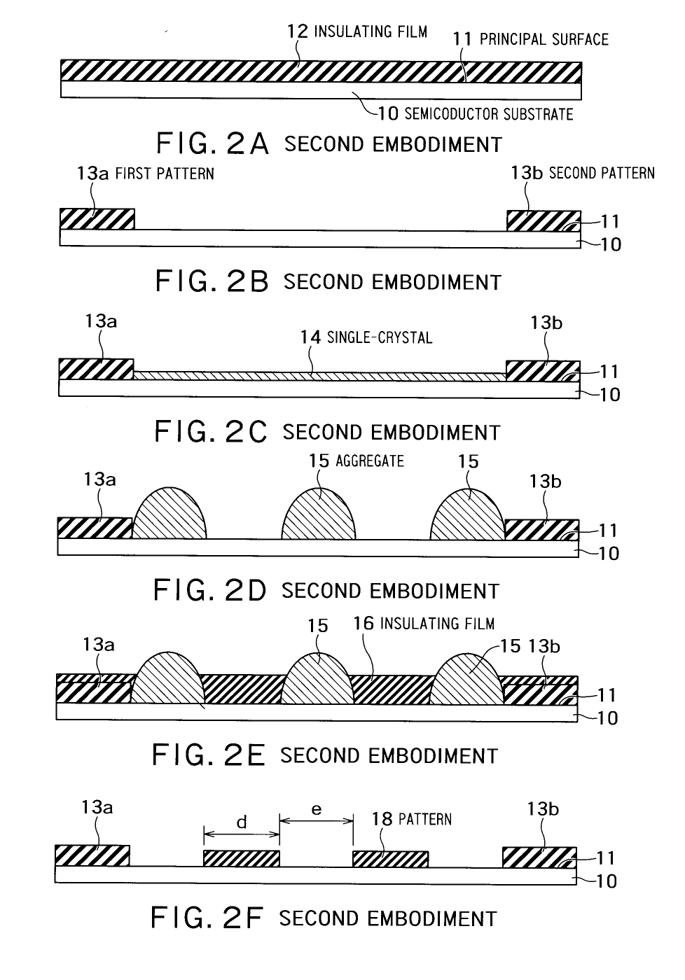

FIG. 2A to FIG. 2F are main-part sectional views illustrating processes of a method for manufacturing a semiconductor device of the second embodiment. In the following embodiments, a component having the configuration identical to that of the first embodiment is designated by the numeral identical to that of the first embodiment, and the description is omitted. The method for manufacturing a semiconductor device of the second embodiment will be described below.

As illustrated in FIG. 2A, the insulating film 12 is formed on the principal surface 11 of a semiconductor substrate 10 by the CVD method, the thermal oxidation method, or the like.

As illustrated in FIG. 2B, the insulating film 12 is patterned to form the first and second pattern 13a and 13b by the photolithographic method, the RIE method, or the like.

Similarly to the first embodiment, the first and second patterns 13a and 13b form the line and space pattern in which the interval and the width are equal to each other. For example, the interval and the width of the first and second patterns 13a and 13b are 90 nm. FIG. 2B to FIG. 2F partially illustrate the first and second patterns 13a and 13b.

As illustrated in FIG. 2C, the single-crystal thin film is epitaxially grown from the semiconductor substrate 10 exposed between the first and second patterns 13a and 13b, thereby forming the single-crystal film 14.

For example, the single-crystal film 14 has the thickness of 10 nm.

Then the single-crystal film 14 is subjected to the annealing process in the deoxidizing ambient such as hydrogen. For example, the annealing process is performed at 600° C. for minutes (for example, for 2 to 3 minutes). The single-crystal film 14 migrated by the annealing process becomes plural aggregates 15 when the temperature is lowered to room temperature. For example, as illustrated in FIG. 2D, the aggregates 15 are migrated at equal intervals based on the aggregates 15 migrated on side-face sides of the first and second patterns 13a and 13b. The plural aggregates 15 are linearly formed between the first and second patterns 13a and 13b. However, the number of aggregates 15 is decreased compared with the first embodiment. For example, the aggregate 15 has the maximum thickness of about 20 nm that is larger than that of the first embodiment.

As illustrated in FIG. 2E, the insulating film 16 is formed on the semiconductor substrate 10 by the CVD method or the like.

As illustrated in FIG. 2F, the aggregates 15 are removed, thereby obtaining plural patterns 18 of the insulating films 16. The plural patterns 18 become a line and space pattern in which the patterns 18 having widths d are arrayed with intervals e between the first and second patterns 13a and 13b. For example, a width d and an interval e of the pattern 18 are equal to each other. For example, the width d and the interval e are 20 nm. Then the semiconductor substrate 10 is processed with the plural patterns 18 as the mask, and the desired semiconductor device is obtained through well-known processes.

In the second embodiment, the number of pieces, the thickness, the width, and the interval of the aggregate 15 formed by the self-organization are controlled by changing the thickness of the single-crystal film 14 epitaxially-grown on the semiconductor substrate 10. However, the invention is not limited to the control method of the second embodiment. For example, the number of pieces, the thickness, the width, and the interval of the aggregate 15 formed by the self-organization may be controlled by changing the interval between the first and second patterns 13a and 13b.

### Effect of Second Embodiment

According to the method for manufacturing a semiconductor device of the second embodiment, the number of pieces, the thickness, the width, and the interval of the aggregate 15 formed by the self-organization can be controlled by changing the thickness of the single-crystal film 14 epitaxially-grown on the semiconductor substrate 10 or the interval between the first and second patterns 13a and 13b.

### Third Embodiment

A third embodiment of the invention differs from the first and second embodiments in that plural trenches 22 are formed on the side of the principal surface 11 of the semiconductor substrate 10.

(Method for Manufacturing Semiconductor Device)

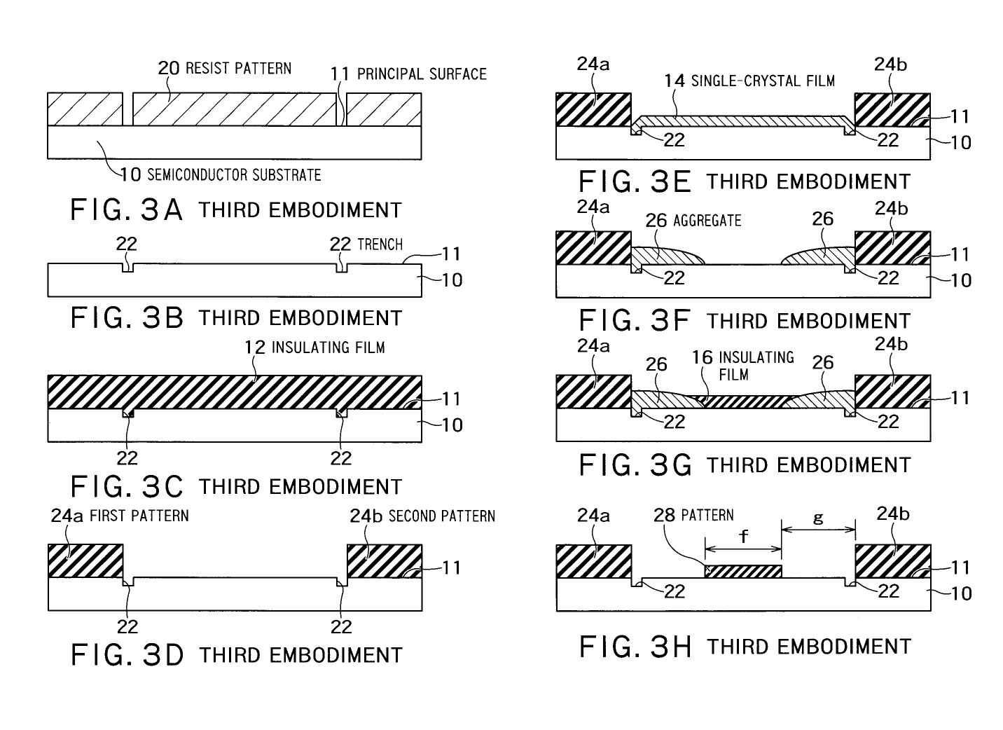

FIG. 3A to FIG. 3H are main-part sectional views illustrating processes of a method for manufacturing a semiconductor device of the third embodiment. The method for manufacturing a semiconductor device of the third embodiment will be described below.

As illustrated in FIG. 3A, a resist pattern 20 is formed on the semiconductor substrate 10. Specifically, for example, a resist film is formed on the semiconductor substrate 10, and a latent image of a photo mask pattern is formed on the resist film by the photolithographic method. Then the resist film is developed to form the resist pattern 20.

As illustrated in FIG. 3B, after the principal surface 11 is etched by the RIE method or the like with the resist pattern 20 as the mask, the resist pattern 20 is removed to form plural trenches 22. For example, a width and a depth of the trench 22 are 10 nm.

As illustrated in FIG. 3C, the insulating film 12 is formed on the semiconductor substrate 10 by the CVD method or the like.

As illustrated in FIG. 3D, the insulating film 12 is patterned to form first and second patterns 24a and 24b by the photolithographic method, the RIE method, or the like. The first and second patterns 24a and 24b are formed such that at least a bottom portion of the trench 22 is exposed.

As illustrated in FIG. 3E, the single-crystal film 14 is epitaxially grown in the principal surface 11 and trenches 22 of the semiconductor substrate 10 exposed between the first and second patterns 24a and 24b.

As illustrated in FIG. 3F, plural aggregates 26 are formed by performing the annealing process in the deoxidizing ambient such as hydrogen. For example, the annealing process is performed at 600° C. for minutes (for example, for 2 to 3 minutes). For example, when the aggregate 15 exists in the trench 22, because a volume of the single-crystal film 14 in the trench region becomes larger than that of another region, the aggregate 26 is easily migrated in the trench 22.

As illustrated in FIG. 3G, the insulating film 16 is formed on the semiconductor substrate 10 by the CVD method or the like.

As illustrated in FIG. 3H, the aggregates 26 are removed, thereby obtaining a pattern 28 of the insulating film 16. The pattern 28 becomes a line pattern in which the pattern 18 is formed in the center of the first and second patterns 24a and 24b. For example, a width f of the pattern 28 is equal to an interval g between the pattern 28 and the first or second pattern 24a or 24b. For example, the width d and the interval e are 10 nm. Then the semiconductor substrate 10 is processed with the pattern 28 as the mask, and the desired semiconductor device is obtained through well-known processes.

### Effect of Third Embodiment

According to the method for manufacturing a semiconductor device of the third embodiment, the aggregate 26 can be migrated near the trench 22 by forming the trench 22 in the semiconductor substrate 10. Additionally, according to the method for manufacturing a semiconductor device of the third embodiment, the position where the aggregate 26 is migrated can be controlled by forming the trench 22 in a desired position.

### Fourth Embodiment

A fourth embodiment of the invention differs from the first to third embodiments in that a step is formed on the side of the principal surface 11 of the semiconductor substrate 10.

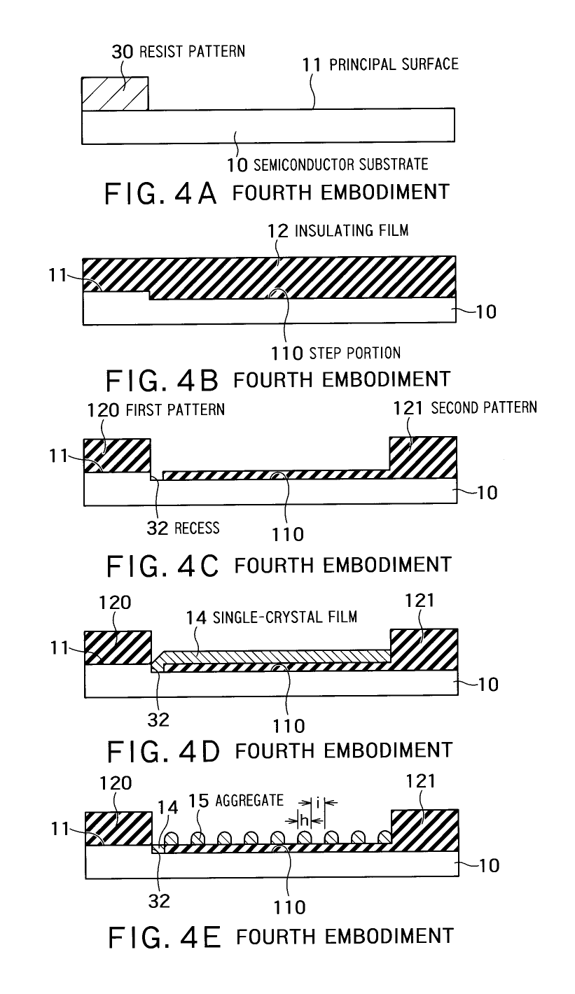

FIG. 4A to FIG. 4E are main-part sectional views illustrating processes of a method for manufacturing a semiconductor device of the fourth embodiment. The method for manufacturing a semiconductor device of the fourth embodiment will be described below.

As illustrated in FIG. 4A, a resist pattern 30 is formed on the principal surface 11 of the semiconductor substrate 10. Specifically, for example, a resist film is formed on the principal surface 11, and a latent image of a photo mask pattern is formed by the photolithographic method. Then the resist film is developed to form the resist pattern 30.

Then, the principal surface 11 is etched to form a step portion 110 by the RIE method or the like with the resist pattern 30 as the mask, and the resist pattern 30 is removed. In the step portion 110, the thickness of the semiconductor substrate 10 is smaller than the thickness of the principal surface 11.

As illustrated in FIG. 4B, the insulating film 12 is formed on the semiconductor substrate 10 by the CVD method or the like.

As illustrated in FIG. 4C, the insulating film 12 is patterned to form a first pattern 120 and a second pattern 121 by the photolithographic method, the RIE method, or the like.

For example, the first pattern 120 is a line pattern formed on the principal surface 11. For example, the second pattern 121 is a pattern formed on the step portion 110, and the pattern has a substantially L-shape in section. The second pattern 121 is formed such that an end portion on the side of the first pattern 120 does not come into contact with the first pattern 120. Therefore, a recess 32 is formed at a boundary between the first pattern 120 and the second pattern 121. The semiconductor substrate 10 is exposed to the bottom portion of the recess 32. For example, the recess 32 has the width of 20 nm and the depth of 10 nm.

As illustrated in FIG. 4D, the single-crystal thin film is epitaxially grown with the semiconductor substrate 10 exposed to the bottom portion of the recess 32 as a seed crystal, thereby forming the single-crystal film 14.

Then the single-crystal film 14 is subjected to the annealing process to form the plural aggregates 15 in the deoxidizing ambient such as hydrogen. For example, the annealing process is performed at 600° C. for minutes (for example, for 2 to 3 minutes). For example, as illustrated in FIG. 4E, the aggregates 15 are migrated on the second pattern 121 at equal intervals based on the aggregate 15 migrated on the side-face side of the second pattern 121. For example, a width h of the aggregate 15 is equal to an interval i between the aggregates 15.

The insulating film 12 is exposed between the aggregates 15. The single-crystal film 14 is exposed in the recess 32.

As illustrated in FIG. 4E, the semiconductor substrate 10 is processed with the plural aggregates 15 as the mask, and the desired semiconductor device is obtained through well-known processes.

### Effect of Fourth Embodiment

According to the method for manufacturing a semiconductor device of the fourth embodiment, the single-crystal film 14 formed on the insulating film 12 is subjected to the annealing process, which allows the migrated single-crystal film 14 to form the plural aggregates 15.

According to the method for manufacturing a semiconductor device of the fourth embodiment, the plural aggregates 15 that are regularly arrayed by the self-organization obtained by the annealing of the single-crystal film 14 is formed on the insulating film 12, and dry etching is subjected to the step portion 110 of the insulating film 12 with the plural aggregates 15 as the mask, which allows the formation of the pattern having the size smaller than the resolution limit of the photolithographic method or the like.

### Fifth Embodiment

A fifth embodiment of the invention differs from the first to fourth embodiments in that the aggregate 15 is formed into an island shape in the principal surface 11 of the semiconductor substrate 10.

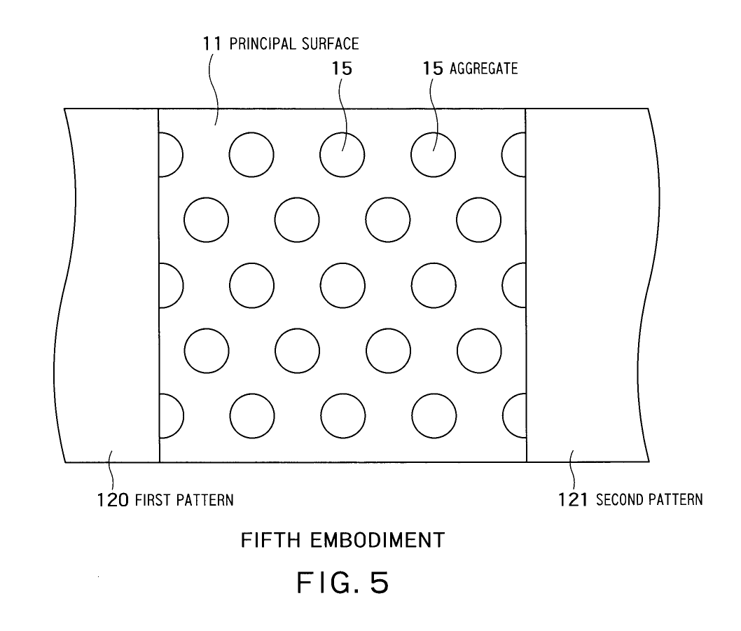

FIG. 5 is a plan view illustrating a semiconductor substrate after the annealing in the method for manufacturing a semiconductor device of the fifth embodiment. The method for manufacturing a semiconductor device of the fifth embodiment will be described below.

An insulating film is formed on the principal surface 11 of the semiconductor substrate 10 by the CVD method, the thermal oxidation method, or the like.

The insulating film is patterned to form the first and second patterns 120 and 121 by the photolithographic method, the RIE method, or the like.

Then the single-crystal film is epitaxially grown with the semiconductor substrate 10 exposed between the first and second patterns 120 and 121 as the seed crystal.

The density of the aggregate 15 after migration is higher when the germanium concentration increases in the single-crystal film. As used herein, the high density means that the number of aggregates 15 per unit area increases. In the fifth embodiment, for example, the single-crystal film is a silicon-germanium film having a germanium concentration of 30%. For example, the single-crystal film has the thickness of 25 nm.

Then the single-crystal film is subjected to the annealing process to form the plural aggregates 15 in the deoxidizing ambient such as hydrogen. For example, the annealing process is performed at 850° C. for one minute.

For example, as illustrated in FIG. 5, the aggregates 15 are migrated at equal intervals based on the aggregates 15 migrated on the side-face sides of the first and second patterns 120 and 121. For example, as illustrated in FIG. 5, the plural aggregates 15 having the island shapes are formed between the first and second patterns 120 and 121.

After the insulating film is formed by the CVD method or the like, the aggregates 15 are removed to form the pattern of the insulating film, the semiconductor substrate 10 is processed with the pattern as the mask, and the desired semiconductor device is obtained through well-known processes.

For example, in the fifth embodiment, the aggregate 15 has a diameter of about 200 nm. A condition is changed to form the aggregates 15. When the interval between the first and second patterns 120 and 121 is 250 nm, the aggregates 15 are formed along the first and second patterns 120 and 121 while coming into contact with the side faces of the first and second patterns 120 and 121. For the interval of 500 nm, the aggregates 15 are formed along the first and second patterns 120 and 121 while alternately coming into contact with the side faces of the first and second patterns 120 and 121. For the interval of 1000 nm, the aggregates 15 are formed along the side faces of the first and second patterns 120 and 121, and the aggregates 15 are also formed while arrayed in the center of the first and second patterns 120 and 121.

### Effect of Fifth Embodiment

According to the method for manufacturing a semiconductor device of the fifth embodiment, the plural aggregates 15 having the island shapes can regularly arrayed. For example, the regular formation of the aggregates 15 can be used in the process of a method for manufacturing a semiconductor device in which openings are regularly formed.

### Sixth Embodiment

A sixth embodiment of the invention differs from the first to fifth embodiments in that the aggregates 15 are formed on the insulating film 12 while a composition of the single-crystal film 14 changes.

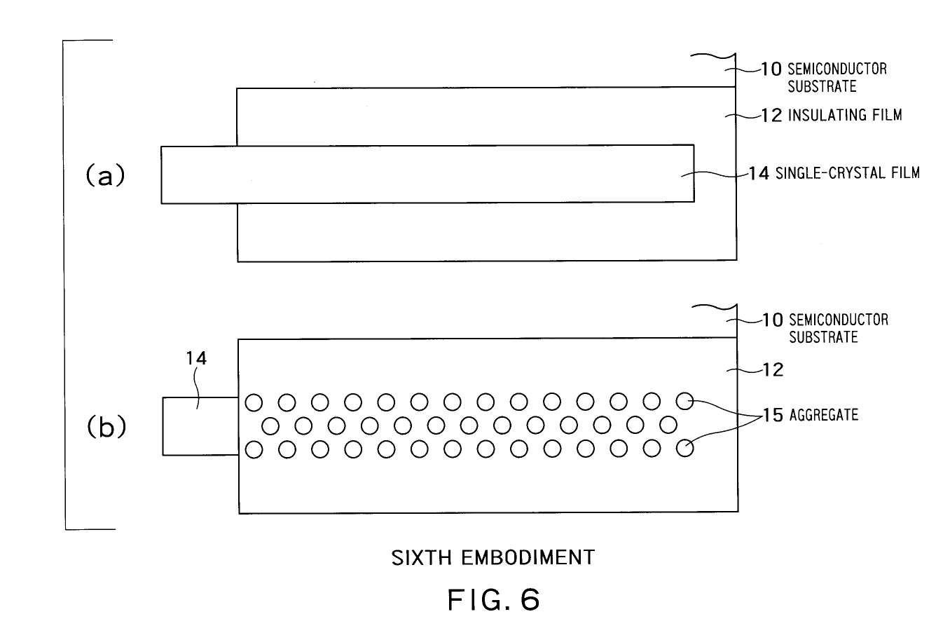

FIG. 6 (a) is a plan view illustrating a semiconductor substrate before the annealing process in a method for manufacturing a semiconductor device of the sixth embodiment of the invention, and FIG. 6 (b) is a plan view illustrating the semiconductor substrate after the annealing process. The method for manufacturing a semiconductor device of the sixth embodiment will be described below.

In the first to fifth embodiments, the single-crystal film 14 is formed between the structures, the single-crystal film 14 is subjected to the annealing process to generate the migration, and the temperature of the single-crystal film 14 is lowered to form the plural aggregates 15. On the other hand, in the sixth embodiment, the epitaxial crystal is formed on the structure from the seed crystal exposed below the structure, and the epitaxial crystal on the structure is subjected to the annealing process to migrate the epitaxial crystal, and the temperature of the migrated epitaxial crystal is lowered to form the plural aggregates on the structure.

As illustrated in FIG. 6 (a), for example, the insulating film 12 is formed on the semiconductor substrate 10, and the single-crystal film 14 is epitaxially grown on the insulating film 12 with the semiconductor substrate 10 as the seed crystal. The silicon-germanium film having the germanium concentration of 40% is used as the single-crystal film 14 in order to easily form the island-shaped aggregate 15.

As illustrated in FIG. 6(b), the single-crystal film 14 on the insulating film 12 is subjected to the annealing process to migrate the single-crystal film 14, the temperature of the migrated single-crystal film 14 is lowered to form the plural aggregates 15. For example, the annealing process is performed at 800° C. for one minute.

For example, as illustrated in FIG. 6 (b), the aggregates 15 having the island shapes are arrayed on the insulating film 12, so that the semiconductor device can be produced with the aggregates 15 as the mask.

### Effect of Sixth Embodiment

According to the method for manufacturing a semiconductor device of the sixth embodiment, the plural aggregates 15 can be formed while regularly arrayed, even if the structure that constitutes the guide does not exist.

In the embodiments, the position where the aggregate 15 is migrated is controlled by forming the structure or the trench 22 as the guide. Alternatively, the position where the aggregate 15 is migrated may be controlled by the difference in surface energy of the surface in which the aggregate 15 is formed.

In the method for manufacturing a semiconductor device of the fourth embodiment, a silicon film may be deposited on the single-crystal film 14. For example, the aggregate 15 is easily formed into the island shape by a strain caused by a difference in lattice constant between the silicon film and the single-crystal film 14. The aggregate 15 is formed while silicon and germanium are mixed, when the silicon film is formed on the single-crystal film 14.

The number of pieces, the thickness, the width, and the interval of the aggregate 15 can be controlled, when the single-crystal film 14 is formed by selecting a plane direction of the semiconductor device 10.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method for manufacturing a semiconductor device, comprising:
forming an epitaxial crystal from a seed crystal exposed between first and second structures;
heating the epitaxial crystal at a temperature equal to or less than a melting point of the epitaxial crystal to migrate the epitaxial crystal; and
migrating the epitaxial crystal to form a plurality of aggregates between the first and second structures.

2. The method for manufacturing a semiconductor device according to claim 1, wherein the first and second structures form a line and space pattern, and
the plurality of aggregates form a line and space pattern between the first and second structures.

3. The method for manufacturing a semiconductor device according to claim 1, further comprising:
forming an insulating film so as to cover surfaces of the plurality of aggregates and a surface of the seed crystal exposed between the first and second structures; and
removing the plurality of aggregates to form a pattern of the insulating film.

4. The method for manufacturing a semiconductor device according to claim 1, wherein the seed crystal is a silicon crystal.

5. The method for manufacturing a semiconductor device according to claim 1, wherein the epitaxial crystal is a germanium crystal.

6. The method for manufacturing a semiconductor device according to claim 1, wherein the first and second structures are a material having a melting point higher than that of the epitaxial crystal.

7. The method for manufacturing a semiconductor device according to claim 1, wherein the first and second structures are a silicon oxide film.

8. The method for manufacturing a semiconductor device according to claim 1, wherein the number of aggregates, thicknesses of the plurality of aggregates, and a width of a line and space formed by the plurality of aggregates are controlled by adjusting a thickness of the epitaxial crystal.

9. The method for manufacturing a semiconductor device according to claim 1, further comprising forming a plurality of trenches on a surface of the seed crystal exposed between the first and second structures.

10. The method for manufacturing a semiconductor device according to claim 1, further comprising forming a step on a surface of the seed crystal exposed between the first and second structures.

11. The method for manufacturing a semiconductor device according to claim 1, wherein each of the plurality of aggregates has an island shape, and the plurality of aggregates are regularly arrayed between the first and second structures.

12. A method for manufacturing a semiconductor device, comprising:
forming an epitaxial crystal on a structure from a seed crystal exposed below the structure;
heating the epitaxial crystal at a temperature equal to or less than a melting point of the epitaxial crystal to migrate the epitaxial crystal; and
migrating the epitaxial crystal to form a plurality of aggregates on the structure.

13. The method for manufacturing a semiconductor device according to claim 12, wherein each of the plurality of aggregates has an island shape, and the plurality of aggregates are regularly arrayed on the structure.

14. The method for manufacturing a semiconductor device according to claim 12, further comprising:
forming an insulating film so as to cover surfaces of the plurality of aggregates and a surface of the seed crystal exposed between the first and second structures; and
removing the plurality of aggregates to form a pattern of the insulating film.

15. The method for manufacturing a semiconductor device according to claim 12, wherein the seed crystal is a silicon crystal.

16. The method for manufacturing a semiconductor device according to claim 12, wherein the epitaxial crystal is a germanium crystal.

17. The method for manufacturing a semiconductor device according to claim 12, wherein the first and second structures are a material having a melting point higher than that of the epitaxial crystal.

18. The method for manufacturing a semiconductor device according to claim 12, wherein the first and second structures are a silicon oxide film.
